(19) United States
(12) Patent Application Publication
(10) Pub. No.: US 2026/0143623 A1
(43) Pub. Date: May 21, 2026

(54) MODULAR, CONTAINERIZED SYSTEM FOR DATA CENTER BALANCE OF PLANT INFRASTRUCTURE WITH INTEGRATED ENERGY STORAGE, COOLING, AND POWER DISTRIBUTION

(71) Applicant: Gridworks, Inc., Albuquerque, NM (US)

(72) Inventors: Kevin Bassalleck, Albuquerque, NM (US); Dustin Neel, Albuquerque, NM (US)

(21) Appl. No.: 19/394,361

(22) Filed: Nov. 19, 2025

Related U.S. Application Data
(60) Provisional application No. 63/722,334, filed on Nov. 19, 2024.

(51) Int. Cl. H05K 7/14

(52) U.S. Cl. CPC H05K 7/1492

(57) ABSTRACT

Various configurations of modular data center systems are described to enable a rapidly deployable data center that can be scaled to the demand and deployed more efficiently with significantly less field construction labor requirements. The systems include combinations of any number of separate IT modules, energy storage modules and transformer modules. A control and monitoring system monitors power demand of the IT equipment of the IT module, controlling power flow between the IT equipment of the IT module and the energy storage module, and balancing the network data load in response to compute load variations experienced by the IT equipment. In another configuration, a single module may include all IT equipment, energy storage and transformers/power conversion subsystems necessary for it to serve as a standalone data center unit.

### CROSS-REFERENCE TO RELATED APPLICATIONS

This application claims priority to and the benefit of the filing of U.S. Provisional Patent Application No. 63/722,334, entitled “Modular, Containerized System for Data Center Balance of Plant Infrastructure with Integrated Energy Storage, Cooling, and Power Distribution”, filed on Nov. 19, 2024, and the specification thereof is incorporated herein by reference.

### BACKGROUND OF THE INVENTION

### Field of the Invention

Embodiments of the present invention relate to a modular, containerized system for data center balance of plant infrastructure with integrated energy storage, cooling, and power distribution.

### Description of Related Art

The infrastructure for modern data centers requires robust power distribution, cooling, and energy storage to support high-demand information technology (IT) operations. Current modular energy storage solutions focus on general-purpose energy storage or grid support, with limited adaptability for the data center's specialized needs, including high-density data processing and specific IT equipment cooling. These solutions often lack the flexibility to integrate seamlessly with medium-voltage power distribution, scalable demand response, and customized cooling for computation clusters.

Modern data centers often require high-density, reliable, and flexible power distribution and cooling systems to support Artificial Intelligence (“AI”) and cloud computing loads. Current modular energy storage or containerized data center systems often operate as discrete elements—energy storage modules serving grid support or backup roles, and IT containers serving compute roles—without deep integration of power, energy, and thermal systems. This separation increases cost, reduces efficiency, and delays deployment.

Typically, large data centers are built to be housed in massive buildings, the sites for which are chosen primarily if not solely based on what a reliable electrical utility can support. However, data center site selection should have more flexibility than that. There is a growing need to site data centers based on other factors, for example real estate prices, specialized labor availability, location of the demand for data center services, etc. The construction of such massive data centers requires a great deal of specialized labor that needs to travel to the site of construction to construct the data center and coordinate all of the balance-of-plant systems, exacerbating the expense of construction and often delaying construction. Once in operation, these large data center housings, due to their physical size, are incredibly inefficient in terms of power distribution topology, energy usage, cooling, and other balance of plant functions. Despite the foregoing problems, data centers continue to be built so inefficiently.

There is a present need for a modular, containerized system that integrates energy storage systems, uninterruptable power supply (“UPS”) functionality, power conversion, and thermal management directly with the information technology (“IT”) load to provide dynamic power management, faster deployment, and reduced capital and operational costs.

What is needed is a standardized data center module that integrates data center balance-of-plant infrastructure, including liquid-cooled thermal management systems, power distribution, power conversion, and energy storage equipment, with the IT hardware, into a rapidly deployable module that can be scaled to the demand and deployed more efficiently with significantly less field construction labor requirements. Standardization would dramatically lower costs per watt. Modularity would allow for the integration of more efficient balance-of-plant infrastructure.

### BRIEF SUMMARY OF EMBODIMENTS OF THE PRESENT INVENTION

Embodiments of the present invention are directed to various configurations of a modular data center system. The system preferably includes an information technology (“IT”) module comprising: an enclosed structure comprising a first side wall and a second side wall, the first side wall and second side wall substantially parallel to a primary axis extending along the length of the IT module; a first end wall; a second end wall; a floor; a ceiling; and subsystems disposed within the enclosed structure, the subsystems comprising IT equipment comprising at least one computer server or data storage device. The system also preferably includes a first energy storage module comprising: an enclosed structure comprising a first side wall and a second side wall, the first side wall and second side wall substantially parallel to a primary axis extending along the length of the first energy storage module; a first end wall; a second end wall; a floor; a ceiling; and at least one energy storage device disposed within the enclosed structure capable of providing a power supply to the IT module. The system also preferably includes a power conversion system capable of electrically coupling the IT module with the first energy storage module, the power conversion system comprising a DC or AC connection; and a control and monitoring system disposed within either or both of the IT module or the energy storage module, the control and monitoring system capable of: monitoring power demand of the IT equipment of the IT module; controlling power flow between the IT equipment of the IT module and the energy storage module; and balancing the network data load in response to compute load variations experienced by the IT equipment. The power conversion system may include at least one of a DC/DC converter, a DC/AC inverter, or an interface to medium-voltage transformer. The system may include a transformer module comprising: an enclosed structure; and electrical transformers disposed within the enclosed structure, the electrical transformers having a voltage range of about 1 kV to about 36 kV. The system may also include a thermal management system disposed within the IT module, the thermal management system comprises air, heat pump, or liquid-cooling configurations including direct-to-chip, on-chip, or immersion cooling systems. The system may also include a fire detection and suppression system disposed within the IT module. The IT module further may also include an energy storage system including at least one energy storage device disposed within the enclosed structure of the IT module. The control and monitoring system may be capable of providing uninterruptable power supply to the IT equipment of the IT module. The control and monitoring system may provide information related to the energy flow, temperature management, and load balancing of the IT equipment in the first IT module tailored to data center operations.

Embodiments of the present invention are also directed to various configurations of the enclosed structure of the IT module. For example, the IT equipment of the IT module may be disposed in first and second rows oriented parallel to the primary axis of the IT module, the first and second rows separated by a distance (referred to herein as the “accessway”) running parallel to the primary axis. The IT equipment may be disposed on a support frame that permits the IT equipment to move substantially perpendicular to the primary axis of the IT module, and the first wall and the second wall of the IT module are adjustable or openable to create an opening through which the IT equipment can extend on its support frame, thereby expanding the space within the accessway when the IT equipment extends through the first wall or the second wall, which expansion of space is adequate to permit a human to pass through or along the accessway to access that side of the IT equipment. The first IT module may also include a space extending at least partially from the first end wall to the second end wall and parallel to the primary axis (this space referred to as “central spine”), wherein the central spine includes any combination of racks, ducts, cable trays, wire baskets, hooks, and/or other devices to manage cables, lines, and cords necessary for distribution of power and thermal management and any other components of the subsystems. The enclosed structure of each the IT module and energy storage module may have a substantially rectangular shape with a length between about 10 feet and about 100 feet, and width between about 6 feet and about 24 feet, so that they can fit on typical transport trucks for transportation on roads.

The separate modules of the present invention are also connectable in arrays in various ways. For example, the first energy storage module may be AC-coupled to the first IT module through inverter-based interfaces. The first energy storage and the first IT module may be DC-coupled to a common DC connection supplying the IT equipment of the first IT module without intermediate AC conversion.

The various modules of the present invention may also be configured in arrays. For example, the system may include a plurality of IT modules each comprising the features of the IT module described above, and a plurality of energy storage modules each comprising the features of the energy storage module described above, each of the plurality of IT modules and plurality of energy storage modules in electrical communication with the transformer module described above. The ratio of the number of the plurality of energy storage modules to the number of the plurality of IT modules depends on the energy requirements of the plurality of IT modules and the energy supply capabilities of the plurality of energy storage modules.

Embodiments of the present invention are also directed to a modular data center system that can itself serve as the data center without the need to connect to a separate modular energy storage system. For example, such a modular data center system preferably includes an information technology (“IT”) module comprising: an enclosed structure comprising a first side wall and a second side wall, the first side wall and second side wall substantially parallel to a primary axis extending along the length of the IT module; a first end wall; a second end wall; a floor; a ceiling; subsystems disposed within the enclosed structure, the subsystems comprising IT equipment, energy storage system, and a power conversion system, wherein the IT equipment comprises at least one computer server or data storage device, wherein the energy storage systems comprise batteries capable of providing power to the IT equipment, wherein the power conversion system comprises at least one of a DC/DC converter, a DC/AC inverter, or an interface to medium-voltage transformer; a control and monitoring system disposed within the IT module, the control and monitoring system capable of: monitoring power demand of the IT equipment in the IT module; controlling power flow between the IT equipment of the IT module and the energy storage systems; and balancing the network data load in response to compute load variations experienced by the IT equipment; and wherein the IT module, the power conversion system, and the energy storage systems are disposed within the IT module or otherwise integrated with the first IT module. The control and monitoring system of the IT module may be capable of providing uninterruptable power supply to the IT equipment.

Embodiments of the present invention are also directed to methods of operating a modular data center. For example, a method for operating a modular data center includes: monitoring power demand of a first information technology (“IT”) module, wherein the first information technology (“IT”) module comprises: an enclosed structure comprising a first side wall and a second side wall, the first side wall and second side wall substantially parallel to a primary axis extending along the length of the IT module; a first end wall; a second end wall; a floor; a ceiling; and subsystems disposed within the enclosed structure, the subsystems comprising IT equipment, wherein the IT equipment comprises at least one of a server or data storage device; and a control and monitoring system disposed within the IT module; controlling power flow between the first IT module and a first energy storage module through a shared DC or AC connection, the first energy storage module comprising: an enclosed structure comprising a first side wall and a second side wall, the first side wall and second side wall substantially parallel to a primary axis extending along the length of the first energy storage module; a first end wall; a second end wall; a floor; a ceiling; an energy storage device disposed within the enclosed structure capable of providing a power supply to the IT equipment; a power conversion system capable of electrically coupling the first IT module with the first energy storage module; and dynamically charging or discharging the first energy storage module in response to compute load variations experienced by the IT equipment.

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWINGS

The accompanying drawings, which are incorporated into and form a part of the specification, illustrate one or more embodiments of the present invention and, together with the description, serve to explain the principles of the invention. The drawings are only for the purpose of illustrating one or more embodiments of the invention and are not to be construed as limiting the invention. In the drawings:

FIG. 1 is an illustration of a perspective view of an information technology module according to an embodiment of the present invention;

FIG. 2 is a plan-view illustration of an information technology module according to an embodiment of the present invention;

FIG. 3 is a plan-view illustration of a module according to an embodiment of the present invention that may serve as a single integrated data center unit; and

FIG. 4 is a plan view illustration of an array of information technology and energy storage modules in coordination with transformer modules as may be in use at the site of intended use, according to an embodiment of the present invention.

It is noted that while the figures may include text identifying/describing a particular object illustrated, such text shall be considered an additional description of that object in addition to whatever this application describes of that object using the reference numbers. In other words, the text in a figure describing an object shall not limit the scope of what is otherwise described.

### DETAILED DESCRIPTION OF THE INVENTION

Embodiments of the present invention are directed to a modular, containerized system tailored for quick deployment of data center infrastructure. The present invention addresses the problems and gaps discussed in the background by providing a scalable, containerized system that integrates components essential for data center operations, including adaptable cooling, load-specific power distribution, and sophisticated control and monitoring systems for IT hardware. The present invention offers rapid deployment, flexibility for various cooling configurations, and compatibility with transformers for high-voltage AC connections.

Embodiments of the present invention are directed to a modular, containerized data center system that integrates IT, energy storage, power conversion, and cooling systems into pre-engineered transportable modules. The system is designed to rapidly deploy and scale data center capacity while maintaining high electrical and thermal efficiency.

### Modular Data Center Architecture

Some embodiments of the present invention include IT modules, energy storage modules, and transformer or power conversion system (“PCS”) modules designed for standardized dimensions suitable for truck or rail transport. Each module can be deployed independently or combined in an array configuration to create a scalable data center infrastructure.

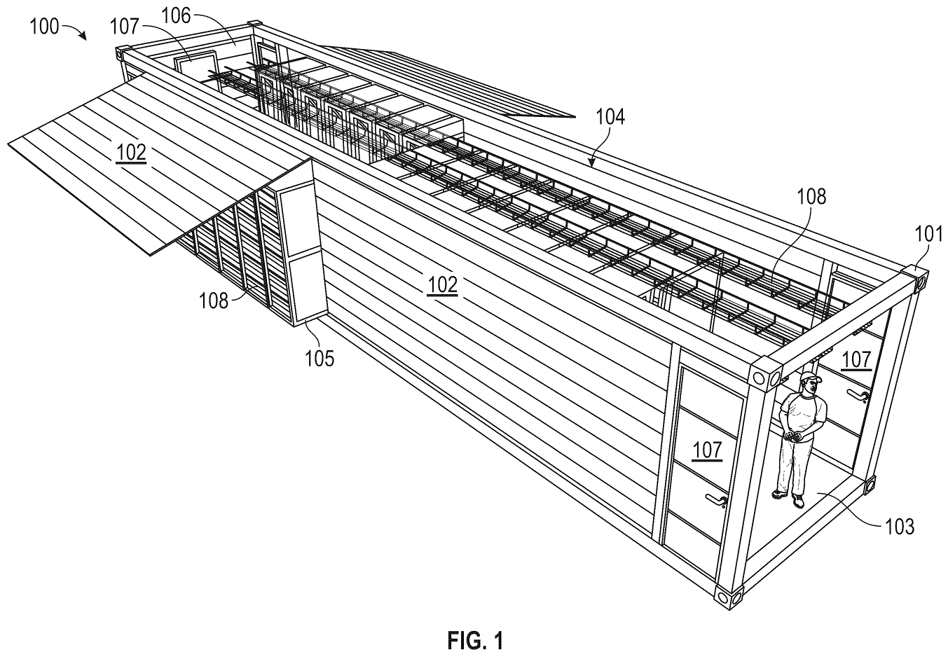

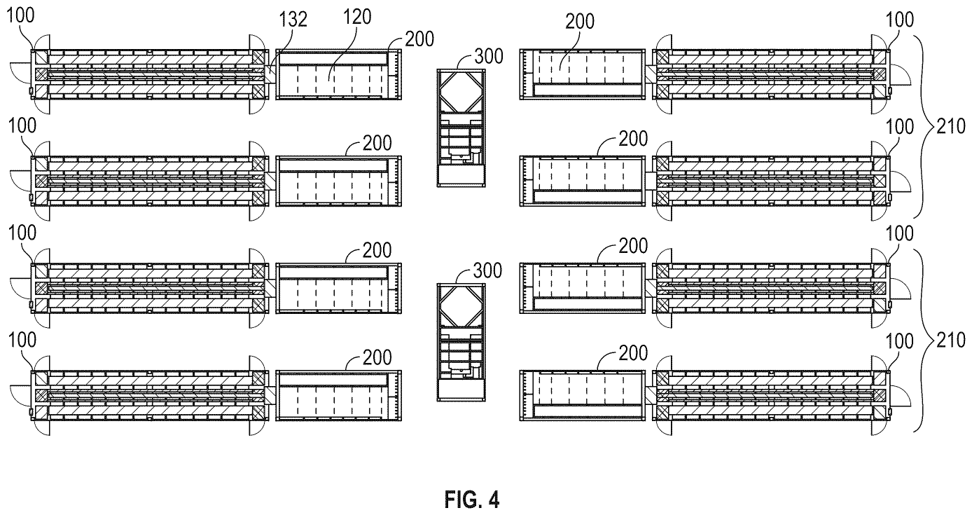

One of the objectives of the present invention is to provide a data center that is modular. Modularity makes it possible to manufacture and deploy the present invention efficiently. That is, IT module 100, energy storage module 200 and transformer module 300 (or a power conversion system that integrates inverters with a transformer) of the present invention are preferably designed, fabricated, and assembled before it is transported to and installed at the site of intended use for operation. This avoids the need to send a great deal of specialized labor to the site of an intended data center to construct the data center. Instead, personnel with the experience and knowledge in data center construction can work at an established manufacturing facility to construct standardized modules that will form the “data center”, to be delivered module by module to the site of operation. The “data center” of the present invention may be a single IT module 100, as illustrated in FIGS. 1-3, or an array of IT modules 100, as illustrated in FIG. 4, depending on the scale of infrastructure needed for a particular site. Whatever the case, each IT module 100, energy storage module 200 and transformer module 300 are preferably constructed prior to delivery to the site.

Modularity, in a conceptual sense as is perhaps used in the engineering arts, is the idea that certain functions, operations, systems and apparatuses can be combined to form a single unit that now has enhanced capabilities or purposes due to its treatment as a unit. The term “module”, as used herein, is intended to refer only to the concept that is described, what is referred to as a unit. The term “module” itself is not intended to impart any particular structure or feature. The term “module” need not require that the module can operate as a data center independently; it may still need to be connected to other objects to operate. Each IT module 100 is one unit of the larger “data center” system or even the entire data center itself. The terms “module” and “container” may be used interchangeably in that sense.

Perhaps as best illustrated in FIG. 1, IT module 100 comprises an enclosed structure formed by frame 101, walls 102, floor 103 and ceiling 104 (the ceiling is not shown in FIG. 1 in order to show what is inside the IT module 100). One might refer to IT module 100 as a “container” in that it is intended to be capable of containing all systems of IT module 100 within in it, although some systems may extend through or outside of IT module 100, for example any power distribution interfaces that connect with systems outside of IT module 100. Energy storage module 200 would also have similar such enclosure/container features as IT module 100. As used herein, the term “enclosed” shall mean that the object is substantially surrounded by objects (e.g., walls, floors, ceiling, framing, etc.) to create a space that generally separates it from the environment; such term “enclosed” shall not be interpreted to require a perfect environmental seal or to mean that there are absolutely no holes or spaces in such enclosure open to the environment.

The particular materials by which IT module 100 is formed and shaped may differ between embodiments but is preferably a durable and rigid material adequate to support the weight of the systems or equipment of IT module 100 while protecting them from the elements for the intended operational life of IT module 100, including but not limited to metals, alloys, wood, plastics etc., and any combination thereof. Energy storage module 200 would also have similar features as IT module 100.

The goal of modularity is enhanced if IT module 100, energy storage module 200 and transformer module 300 comprise a shape and size that is capable of transport by standard means; for example, so that IT module 100 can fit on the trailer of a semi-truck to permit delivery of the IT module 100 to a site without the need for specialized or unique transportation vehicles. To that end, the modules are preferably rectangular. Preferably, the length of any IT module 100, energy storage module 200 and transformer module 300 is between about ten feet (three meters) and about one hundred feet (thirty meters), more preferably between about twenty feet (six meters) and about sixty feet (eighteen meters), and most preferably between about twenty feet (six meters) and about forty feet (twelve meters). The width is preferably between about six feet (two meters) and about twenty-four feet (seven meters), more preferably between about eight feet (two meters) and about twelve feet (four meters) and most preferably between about eight feet (two meters) and about ten feet (three meters).

Additional features of the physical characteristics of IT module 100, energy storage module 200 and transformer module 300 are described below. As used herein, the term “primary axis” shall refer to that axis in the direction of and/or along the length of the given module.

### Subsystems of Module 100

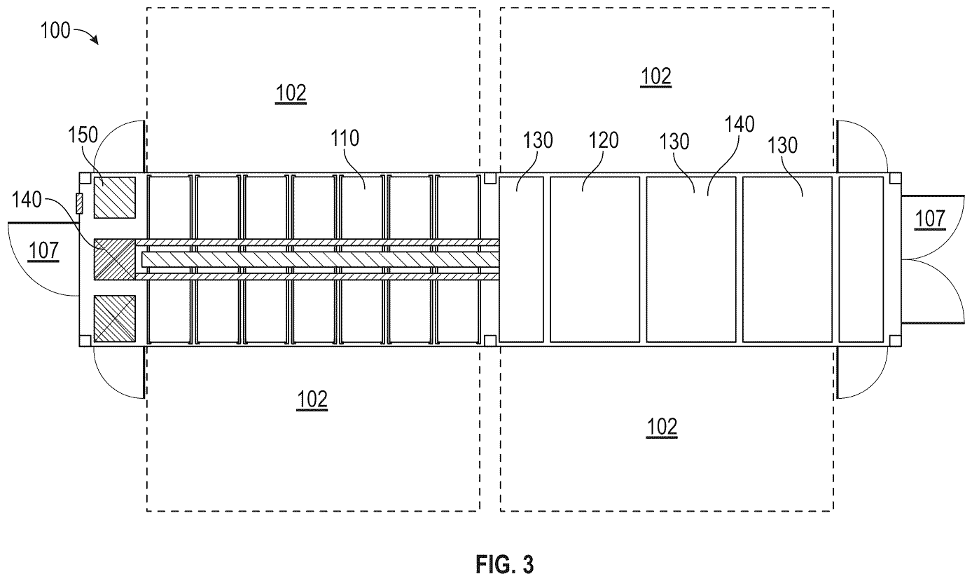

FIGS. 1-4 all illustrate various embodiments of IT module 100 of the present invention. Each IT module 100 comprises a set of systems for data center operations, each of FIGS. 1-4 showing IT modules 100 comprising different sets of systems. The subsystems include any combination of, but are not limited to, IT systems 110 (sometimes referred to herein as IT equipment), energy storage systems 120, power conversion systems 130, thermal management systems 140, fire detection and suppression systems 150, and control and monitoring systems 160, each of which will be further described herein. The set of systems of IT module 100, which may be referred to collectively herein as “subsystems”, may differ between embodiments, as needed for the particular application. For example, FIGS. 1, 2 and 4 illustrate versions of IT module 100 that do not necessarily include energy storage systems 120 within the module itself. In those embodiments, a separate module, for example energy storage module 200 as illustrated in FIG. 4, would provide energy storage systems 120 to IT module 100 in the system of the present invention. In comparison, FIG. 3 is an example of IT module 100 comprising energy storage systems 120 as a subsystem of the module itself in addition to IT systems 110, in which case such embodiment may serve as its own standalone data center that does not require power from additional energy storage module 200. However, any combination of the foregoing may be possible depending on the application. For example, in some embodiments, IT module 100 includes energy storage system 120 within its enclosure as illustrated in FIG. 3 but is also coupled to energy storage module 200.

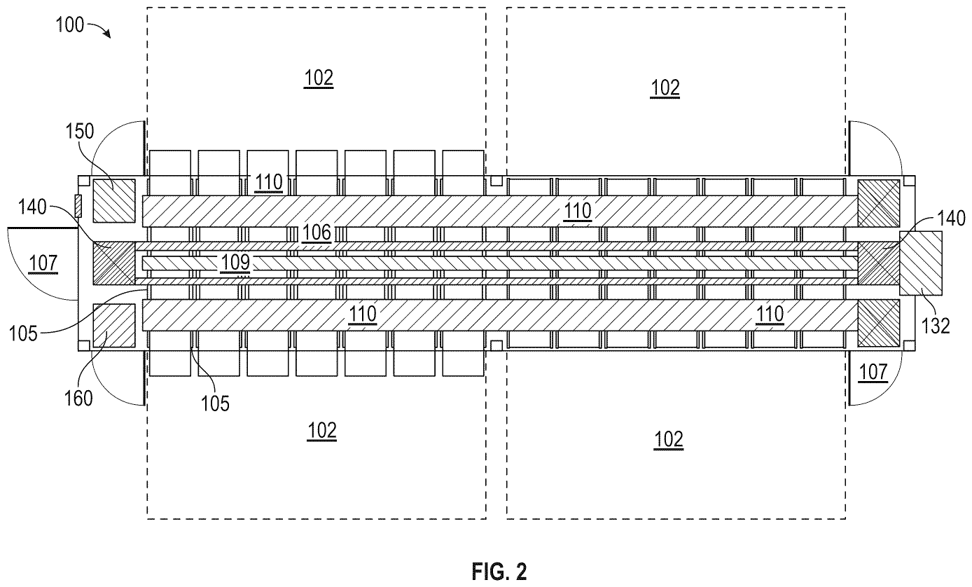

The subsystems may be disposed within IT module 100 at any location on, in or within it, with any orientation, preferably located to maximize the use of the space within IT module 100. For example, referring to FIG. 2 illustrating IT module 100 in which a majority of the space within the module is dedicated to IT Systems 110, there are two parallel rows of IT systems 110. In another embodiment, for example as illustrated in FIG. 3, a first section of IT module 100 comprises two parallel rows of IT systems 110 and a second portion comprises a single row of other subsystems, including energy storage systems 120, power conversion systems 130, thermal management systems 140. Subsystems may be disposed on floor 103 directly, on a support frame 105, including for example racks, on ceiling racks 108, or any other configuration as may be desired. To prevent damage to a subsystem during transportation of IT module 100, subsystems are preferably secured to IT module 100 as needed. Support frame 105 can include, but is not limited to, racks, immersion cooling tanks, and other cooling systems, or ceiling racks 108.

### Accessibility of Subsystems of it Module 100

Given that the subsystems, for example IT systems 110, often need to be accessed for maintenance, testing, and replacement once IT module 100 is in operating at the site, the present invention contemplates a way to maximize the use of space within IT module 100 while providing access to subsystems. Referring to FIGS. 1 and 2, certain components of IT systems 110, for example data servers, are disposed on support frame 105 capable of sliding IT systems 110 in a direction that is perpendicular to the primary axis of IT module 100. Of course, other subsystems may also be disposed on support frame 105. In whatever case, at least some portion of at least one wall 102 of IT module 100 are adjustable to permit any subsystem of IT module 100, for example IT system 110, to extend at least partially beyond the location of the walls when closed. Referring to FIG. 1 for example, wall 102 opens by extending upwards to create an opening through which IT system 110 can extend on its racks. In such case, wall 102 may comprise hinges at or near the end of module that is its ceiling 104. In other embodiments, wall 102 may slide in the direction of the primary axis, like a sliding door, along tracks at or near floor 103 or ceiling 104 or may simply be removable from IT module 100 entirely. In whatever case, wall 102 may be referred to herein as having an “open” position that permits a subsystem to extend outside of what would be the wall of IT module 100, and a “closed” position that encloses IT module 100.

In the open position of any wall 102, when the subsystem is extended at least partially outside IT module 100, space is created within IT module 100 that may serve as an aisle 106 through which a person may pass to access the backside of the subsystems. To that end, IT module 100 preferably also comprises at least one access door 107 that permits a person to enter into IT module 100 to access subsystems, including by passing through aisle 106.

### IT Systems 110

Each IT module 100, as a unit of a “data center” system, comprises IT Systems 110 performs the information technology/“data center” functions of the present invention, which may include but is not limited to servers, data storage devices, network switches, routers, and all cables and adaptors necessary for the foregoing. The number of servers and data storage devices in a given IT module 100 depends on their size, the intended capabilities, and their energy requirements. IT module 100 is connected to information technology infrastructure, telecommunications networks or various digital networks through various ports and cables or wirelessly, and may include various ports in its enclosed structure for the same. In this way, the IT systems 110 disposed within IT module 100 receive data from such networks to store such data and/or perform operations on such data, as may be carried out by computer processors within IT systems 110 pursuant to programmed instructions stored therein or in some other data storage device connected to the network.

Given that IT systems 110 often need to be accessed for maintenance, testing, and replacement, IT systems 110 are preferably disposed on support frame 105 as described above, but in some embodiments, they may simply be secured to or otherwise disposed on floor 103 within IT module 100.

### Energy Storage Systems 120 of IT Module 100 or of Energy Storage Module 200

Energy storage systems 120 may comprise any type of energy storage device, for example, a battery energy storage systems (“BESS”), flywheels, supercapacitors, etc., that provide scalable energy storage, flexible demand response, and uninterrupted backup power for critical IT operations. Energy storage systems 120 that comprise a BESS, the BESS provides:
UPS-grade ride-through power to ensure continuous IT operation during transient disturbances;
Dynamic load management to smooth load fluctuations and ramp rates; and
Flexible demand response capabilities to optimize energy costs and stabilize grid or generator interfaces.

The energy storage system may be DC-coupled to the IT load through a common DC bus, or AC-coupled through inverter-based interfaces. Either configuration supports seamless bidirectional energy exchange and site-level stability.

Energy storage systems 120 preferably comprise batteries that provide scalable energy storage and flexible demand response to smooth power peaks and ensure backup power for critical IT operations. In some embodiments, for example as illustrated in FIG. 3, IT module 100 comprises energy storage systems 120 within or as a subsystem of IT module 100 itself. In other embodiments, for example as illustrated in FIG. 4, some, or all of the energy storage systems 120 necessary to power IT systems 110 are contained in a separate module that we refer to as energy storage module 200.

Regarding embodiments of the invention that employ energy storage module 200, various configurations or “arrays” are contemplated. FIG. 4 shows an example of an array of IT modules 100 each powered by its own dedicated energy storage module 200. However, different arrays and configurations are also contemplated. For example, in some embodiments, a single energy storage module 200 may support the energy requirements of a plurality of IT modules 100. In such case, one might configure the array such that there is an IT module 100 disposed adjacent to or near a first and a second side of energy storage module 200. The electrical connections between them are made by coupling interfaces disposed on both, for example coupling interface 132 of IT module 100 with a corresponding electrical coupling interface on energy storage module 200. The ratio of the number of energy storage modules 200 to IT modules 100 depends on the energy requirements of the IT modules 100 and the energy supply capabilities of the energy storage modules 200.

### Power Conversion Systems 130 and Power Distribution

Power conversion systems preferably manage power conversion and adaptation across modules. Embodiments of the present invention preferably include an integrated DC bus and shared power architecture that enables both the energy storage module 200 and IT module 100 to connect to a common DC link. However, any AC or DC connection may be employed, depending on the particular configuration desired. As used herein, the term “connection” shall be interpreted broadly to refer to any type of electrical connection necessary to accomplish the subject feature, including but not limited to busses, cables, etc. Power conversion equipment may include, but is not limited to, DC/DC converters, DC/AC inverters, and interfaces to medium-voltage transformers, any of which may be implemented in various ways depending on the embodiment of the invention. This architecture eliminates redundant conversion stages typical in conventional rack-level UPS systems, reducing conversion loss and improving power usage effectiveness (“PUE”).

Referring to FIG. 3, energy storage systems 120 and power conversion systems 130 are integrated within the IT module 100 itself. In those embodiments of the modular data center that employ energy storage modules, power conversions systems 130 may also be disposed within energy storage module 200 or any combination of both IT module 100 and energy storage module 200.

In some embodiments, the power conversion system may support hybrid operation where the output of energy storage module 200 (e.g., the BESS) is AC through string inverters and step-up transformers, while maintaining distributed UPS functionality across each module.

Power conversion systems 130 preferably include all the systems, components, and cables necessary to provide any power conversion or adaptation for the subsystems of IT module 100, including but not limited to direct current (DC) to DC converters that direct power supply to IT systems 110, such as CPUs, GPUs, and network equipment. Power conversion systems 130 may comprise DC to alternating current (AC) inverters to convert power to AC for compatibility with external transformers, allowing medium-voltage AC distribution (480 Vac or higher). Power conversion systems 130 may also comprise an interface for transformer connections, which preferably allows for connection of IT module 100 to step-up transformers, for example transformer modules 300 as illustrated in FIG. 4, and allows for power distribution across arrays of energy storage modules 200 and the data center as a whole to be at higher voltages than traditional power distribution in a data center built in a building with lower voltage power distribution. This significantly reduces power loss and reduces power distribution cable sizing, quantity, hardware cost, and installation speed. Unlike existing energy storage containers focused on general power supply, the present invention directly powers CPUs, GPUs, and networking hardware, reducing energy loss and improving efficiency.

Unlike traditional energy storage containers that provide general DC and/or AC power, power conversion systems 130, for example its components of DC-DC converters of the present invention directly serve IT systems 110, reducing conversion losses and supplying power more efficiently to servers, GPUs, and networking equipment. Power conversion systems 130 also preferably comprise DC-AC inverters that allow for seamless integration with transformers that step-up voltage to medium levels (e.g., about 12.47 kV or higher), to support large data center networks. This feature is absent in most other modular container systems, which typically focus on DC-only or low-voltage AC outputs for general energy storage. In these embodiments, DC power distribution busses or cabling will be used for power distribution for both the IT systems 110, and energy storage systems 120 (e.g., DC battery stacks), and any other nominally DC-powered systems within the modules. Both IT systems 110 and energy storage systems 120 will utilize DC-DC converters to allow for sharing of a common voltage DC bus system to suit the needed DC-input of each component. In doing so, multiple DC/AC conversion and power distribution components in a typical AC-based power distribution data center design are eliminated, decreasing cost and improving efficiency.

In some embodiments, energy storage system 120 can include, but is not limited to, at least one battery, flywheels, supercapacitors, ultracapacitors, hydroelectric storage, compressed air energy storage, flow batteries, or a combination thereof.

As illustrated in FIG. 4, each IT module 100 may connect with external transformer modules 300 to distribute power at medium voltage, integrating seamlessly with larger data center infrastructure for rapid scalability. High-voltage AC output compatible with medium-voltage transformers allows for more efficient and lower-cost power distribution across large data centers. Such transformers preferably have a voltage range between about 1 kV and about 69 kV and more preferably between about 1 kV and about 36 kV, and most preferably between about 12 kV and about 36 kV. Typical data center power distribution involves enormous quantities of 480v AC power distribution, which increases power loss and results in higher cost for cabling and installation labor.

To distribute power to subsystems within IT module 100, IT module 100 preferably comprises any combination of ceiling racks 108, ducts 109, cable trays, wire baskets, hooks, and/or other devices to manage the cables, lines, and cords necessary for such distribution. For example, referring to FIG. 2, duct 109 extends along or parallel to the primary axis of IT module 100 from about one end to the other to provide a cavity by which cables for the distribution of DC electrical power to the various subsystems, including IT systems 110.

### Thermal Management Systems 140

In some embodiments, thermal management systems may support air, heat pump, and direct liquid-cooling configurations including, but not limited to, direct-to-chip, on chip, immersion cooling systems, or a combination thereof. In some embodiments, liquid cooling loops for the energy storage system can be hydraulically coupled to cooling loops serving IT systems, allowing shared utilization of pumps, capacitor discharge units (“CDUs”), and heat exchangers. This reduces redundant hardware, improves thermal efficiency, and enables compact modular deployment.

Thermal management systems 140 may comprise air-cooling, heat pump, and preferably liquid cooling systems with direct-to-chip configurations. This flexibility ensures efficient cooling for data center-specific equipment, for example IT systems 110, provides significant improvement in thermal management of the system, lowering balance-of-plant costs. The option for direct-to-chip liquid cooling, air-cooled, and heat pump systems supports high-density data processing loads, addressing a specific need in data centers, making cooling configurations adaptable and multi-modal. The thermal management system with a liquid-cooling design would incorporate shared components (piping, pumps, chillers) that distribute cooling and return coolant within one or more modules. For example, piping and coolant could be shared across a common system that provides liquid-cooling for both IT systems 110, energy storage systems 120, and any other components that can benefit from the advantages of liquid-cooling as opposed to traditional air-cooled systems. This common cooling system can be within a single module with the various components, as depicted in FIG. 3, or coupled between IT module 100 and energy storage module 200 as shown in FIG. 4, along with electrical bussing and communications cabling to connect the modules and share balance-of-plant infrastructure between modules.

Thermal management systems 140 may be disposed within IT module 100 wherever it is best to provide their function and the particular physical requirements of the system. For example, referring to FIG. 2, thermal management systems 140 comprises a liquid cooling system with cold and hot loop lines extending along or parallel to the primary axis of IT module 100 from one end of the module to the other with additional liquid lines extending down into IT systems 110 for direct-to-chip liquid cooling. Components of thermal management systems 140, such as liquid cooling lines, may be attached to and travel along ceiling racks 108 to prevent interference with other objects, which are best illustrated in FIG. 1. Thermal management piping and components could be extended further to adjacent IT modules 100 to further allow for sharing of balance-of-plant components across multiple modules.

### Fire Detection and Suppression Systems 150

Fire detection and suppression systems 150 preferably comprise customized fire suppression mechanisms compatible with sensitive IT hardware and designed for safety in high-density electronic environments. Unlike traditional energy storage units, which may use standard fire suppression, fire detection and suppression systems 150 of the present invention preferably comprise gas-based suppression and advanced sensors to avoid equipment damage, tailored to data center safety standards. Fire detection and suppression systems 150 may be disposed within IT module 100 wherever it is best to provide their function and based on the particular physical requirements of the system.

### Control and Monitoring Systems 160

Embodiments of the present invention may also comprise control and monitoring system 160, which preferably comprises a centralized supervisory control and data acquisition (“SCADA”) and control network to provide dynamic power and thermal management, energy flow monitoring, and predictive load balancing. Control and monitoring system 160 preferably coordinates the charging/discharging of energy storage module 200 (e.g., BESS units) and manages real-time computer power ramping to minimize grid disturbance and maintain system efficiency. In load balancing, control and monitoring system 160 preferably distributes, manages, restricts or otherwise controls network data traffic received by the IT systems 110, distributed across IT systems 110 and/or generated/outputted by IT systems 110 to optimize resource usage, maximize throughput, maximize efficient use of energy received from energy storage systems 120 and/or received from energy storage module 200, and/or minimize response time of IT systems 110.

Control and monitoring systems 160 preferably comprise integrated SCADA and communication systems specific to data center needs, enabling flexible demand response and comprehensive monitoring of power flows, battery status, and temperature. Control and monitoring systems 160 preferably provides detailed insights into energy flow, temperature management, and load balancing tailored to data center operations. Tailored monitoring and control systems enable responsive power management specific to data center IT workloads (the IT systems 110), contrasting with the general load control found in existing energy storage systems. This provides flexible demand response. Control and monitoring systems 160 may be disposed within IT module 100 wherever it is best to provide their function and based on the particular physical requirements of the system.

### Central Spine

As discussed above, IT module 100 preferably comprises any combination of ceiling racks 108, ducts 109, cable trays, wire baskets, hooks, and/or other devices to manage the cables, lines, and cords necessary for distribution of power and thermal management and any other components of the subsystems. Such may be referred to herein as the “central spine” of IT module 100, as efficiency and modularity are enhanced by organizing cables and lines centrally along at least a majority of the length of IT module 100. The central spine can be defined as running parallel to the primary axis of the housing, from the first end of the housing to the second end of the housing. For example, ceiling racks 108 and duct 109 extend along or parallel to the primary axis of IT module 100 from about one end to the other to provide a cavity by which cables for the distribution of DC electrical power and thermal management components to the various subsystems, including IT systems 110.

### System Architecture with Multiple Power Blocks

Embodiments of the present invention can be configured to form data centers with a wide range of operational capacities. The smallest unit of a “data center” for the present invention could be a single IT module 100, for example, the IT module 100 illustrated in FIG. 3 with its own energy storage systems 120. Any number of additional IT modules 100 and/or energy storage modules 200 may be employed to create a data center of any operational capacity. In this way, IT modules 100 and/or energy storage modules 200 can be deployed or removed as needed, including as the data center operational demands change. For example, the ratio of IT modules 100 to energy storage modules 200 in some embodiments can vary to tailor the amount of energy storage/demand response capabilities for each particular application, providing the best possible energy demand management and back-up power potential.

Referring to FIG. 4, a data center network according to an embodiment of the present invention can scale by connecting a plurality of IT modules 100 into what this application may refer to as “power blocks” 210, with each power block 210 comprising transformer module 300 for medium-voltage distribution. This modular network supports a larger data center comprised of one or more power blocks, allowing for customized scaling without extensive retrofitting or redesign.

Preferably, transformer module 300 is also modular, that is, all its components may be disposed on a pad or skid so that it can be constructed prior to delivery to the site and deployed in a similar fashion as IT module 100 and energy storage module 200. In this way, a single manufacturer of IT modules 100, energy storage modules 200 and transformer modules 300 can design and manufacture/assemble all of them as a kit to be transported to the site of operation. The labor required to install IT modules 100, energy storage modules 200 and transformer modules 300 would not require the same level of specialization as is needed in traditional data center construction. Installation simply involves placement and making any necessary connections between IT modules 100, energy storage modules 200 and transformer modules 300 via the standard terminations, plugs and cables made simple at coupling interfaces 132.

### Dynamic Load Management/Balancing and Integrated UPS Functionality

In some embodiments, the invention provides an integrated topology wherein one or more energy storage modules can provide both uninterrupted power supply (UPS) functionality and active load management to the IT modules. This enables dynamic response to real-time computational load variations characteristic of AI training and inference workloads. Unlike traditional UPS systems, the present invention's energy storage modules 200 can be dynamically coupled to IT modules 100 through shared DC or AC buses to provide continuous bidirectional power flow, stabilizing transient load ramps and reducing grid or generator stress.

As used herein, dynamic and active load management refers to the ability of the energy storage modules to change the level of load provided in response to changing circumstances. In one embodiment, such dynamic load management/balancing includes charging or discharging energy storage module 200 in response to compute load transients experienced by IT systems 110 in IT module 100.

### Operational Efficiency and Deployment Advantages

Embodiments of the integrated modular system enable:
Rapid deployment of full-scale data center capability independent of utility grid interconnection;
Reduced generator and transformer sizing due to load-leveling and ramp-rate control;
Elimination of rack-level UPS systems, freeing space for compute racks;
High-efficiency power distribution, for example at about 12.47 kV to about 35 kV, minimizing copper losses and cabling costs.

Embodiments of the described modular system provide a unique integration of energy storage, UPS, cooling, and power distribution specifically tailored to the operational and thermal characteristics of modern data centers, including AI training and inference workloads. The topology enables faster deployment, improved PUE, reduced capital cost, and enhanced grid stability.

### Additional Embodiments

In one embodiment, a modular data center system can include at least one IT module 100 housing IT systems 110, at least one energy storage module 200 comprising a battery energy storage system (BESS), and a power conversion system 130 coupling IT module 100 to energy storage module 200 through a shared DC or AC bus that may be implemented through coupling interface 132. Energy storage module 200 provides uninterrupted power supply to IT module 100 and dynamic load balancing responsive to compute load variations. Energy storage module 200 and IT modules 100 can be DC-coupled through a common DC bus, eliminating separate rack-level UPS systems. The power conversion system can be configured to interface with a medium-voltage transformer with a voltage range of 12.47 kV-35 kV), for example as may be disposed within transformer module 300, for site-level power distribution. The modular data center system can also include liquid cooling loops shared between energy storage module 200 and IT module 100.

### Methods

Embodiments of the present invention are also directed to various methods for operating the modular data centers described in this application.

For example, in one embodiment of a method according to the present invention, a method includes monitoring power demand of IT module 100, controlling bidirectional power flow between the IT module 100 and at least one energy storage module 200 through a shared DC or AC bus; and dynamically charging or discharging the energy storage module 200 in response to compute load transients experienced by IT systems 100 within IT module 100, to stabilize total site power draw.

### Combinations and Variations; Other Definitions

The preceding examples can be repeated with similar success by substituting the generically or specifically described components and/or operating conditions of embodiments of the present invention for those used in the preceding examples.

The terms, “a”, “an”, “the”, and “said” mean “one or more” unless context explicitly dictates otherwise.

Note that in the specification and claims, “about”, “approximately”, and/or “substantially” means within twenty percent (20%) of the amount, value, or condition given. All computer software disclosed herein may be embodied on any non-transitory computer-readable medium (including combinations of mediums).

Embodiments of the present invention can include every combination of features that are disclosed herein independently from each other. Although the invention has been described in detail with particular reference to the disclosed embodiments, other embodiments can achieve the same results. Variations and modifications of the present invention will be obvious to those skilled in the art and this application is intended to cover, in the appended claims, all such modifications and equivalents. The entire disclosures of all references, applications, patents, and publications cited above are hereby incorporated by reference. Unless specifically stated as being “essential” above, none of the various components or the interrelationship thereof are essential to the operation of the invention. Rather, desirable results can be achieved by substituting various components and/or reconfiguring their relationships with one another.

What is claimed is:

1. A modular data center system comprising:
a first information technology (“IT”) module comprising: an enclosed structure comprising a first side wall and a second side wall, the first side wall and second side wall substantially parallel to a primary axis extending along the length of the IT module; a first end wall; a second end wall; a floor; a ceiling; and subsystems disposed within the enclosed structure, the subsystems comprising IT equipment comprising at least one computer server or data storage device;
a first energy storage module comprising: an enclosed structure comprising a first side wall and a second side wall, the first side wall and second side wall substantially parallel to a primary axis extending along the length of the first energy storage module; a first end wall; a second end wall; a floor; a ceiling; and at least one energy storage device disposed within the enclosed structure capable of providing a power supply to the first IT module;
a power conversion system capable of electrically coupling the first IT module with the first energy storage module, the power conversion system comprising a DC or AC connection; and
a control and monitoring system disposed within either or both of the IT module or the energy storage module, the control and monitoring system capable of: monitoring power demand of the IT equipment of the IT module; controlling power flow between the IT equipment of the IT module and the energy storage module; and balancing the network data load in response to compute load variations experienced by the IT equipment.

2. The modular data center system of claim 1 wherein the power conversion system comprises at least one of a DC/DC converter, a DC/AC inverter, or an interface to medium-voltage transformer.

3. The modular data center system of claim 1 further comprising a first transformer module comprising: an enclosed structure; and electrical transformers disposed within the enclosed structure, the electrical transformers having a voltage range of about 1 kV to about 36 kV.

4. The modular data center system of claim 1 further comprising a thermal management system disposed within the first IT module, the thermal management system comprises air, heat pump, or liquid-cooling configurations including direct-to-chip, on-chip, or immersion cooling systems.

5. The modular data center system of claim 1 further comprising a fire detection and suppression system disposed within the first IT module.

6. The modular data center system of claim 1 wherein the first IT module further comprises an energy storage system comprising at least one energy storage device disposed within the enclosed structure of the first IT module.

7. The modular data center system of claim 1 wherein the control and monitoring system is capable of providing uninterruptable power supply to the IT equipment of the first IT module.

8. The modular data center system of claim 1 wherein the IT equipment of the first IT module is disposed in first and second rows oriented parallel to the primary axis of the first IT module, the first and second rows separated by a distance (referred to herein as the “accessway”) running parallel to the primary axis.

9. The modular data center system of claim 8 wherein:
the IT equipment is disposed on a support frame that permits the IT equipment to move substantially perpendicular to the primary axis of the first IT module, and
the first wall and the second wall of the first IT module are adjustable or openable to create an opening through which the IT equipment can extend on its support frame, thereby expanding the space within the accessway when the IT equipment extends through the first wall or the second wall, which expansion of space is adequate to permit a human to pass through or along the accessway to access that side of the IT equipment.

10. The modular data center system of claim 1 wherein the first energy storage module is AC-coupled to the first IT module through inverter-based interfaces.

11. The modular data center system of claim 1 wherein first energy storage and the first IT module are DC-coupled to a common DC connection supplying the IT equipment of the first IT module without intermediate AC conversion.

12. The modular data center system of claim 1 wherein the control and monitoring system provides information related to the energy flow, temperature management, and load balancing of the IT equipment in the first IT module tailored to data center operations.

13. The modular data center system of claim 1 wherein the first IT module comprises a space extending at least partially from the first end wall to the second end wall and parallel to the primary axis (this space referred to as “central spine”), wherein the central spine comprises any combination of racks, ducts, cable trays, wire baskets, hooks, and/or other devices to manage cables, lines, and cords necessary for distribution of power and thermal management and any other components of the subsystems.

14. The modular data center system of claim 3 further comprising a plurality of IT modules each comprising the features of the first IT module, and a plurality of energy storage modules each comprising the features of the first energy storage module, each of the plurality of IT modules and plurality of energy storage modules in electrical communication with the first transformer module.

15. The modular data center system of claim 14 wherein the ratio of the number of the plurality of energy storage modules to the number of the plurality of IT modules depends on the energy requirements of the plurality of IT modules and the energy supply capabilities of the plurality of energy storage modules.

16. The modular data center of claim 1 wherein the enclosed structure of each the first IT module and first energy storage module comprises a substantially rectangular shape with a length between about 10 feet and about 100 feet, and width between about 6 feet and about 24 feet.

17. The modular data center system of claim 1:
wherein the power conversion system comprises at least one of a DC/DC converter, a DC/AC inverter, cabling and connector systems, or an interface to medium-voltage transformer;
further comprising a thermal management disposed within the first IT module comprising air, heat pump, or direct liquid-cooling configurations;
wherein the IT equipment comprises at least one of computer servers or data storage devices;
further comprising a first transformer module capable of electrical connection to the first energy storage module and/or first IT module, the first transformer module comprising: an enclosed structure and at least one electrical transformer disposed within the enclosed structure, the at least one electrical transformer having a voltage range of about 1 kV to about 36 kV;
wherein the control and monitoring system is capable of providing uninterruptable power supply to the IT equipment of the IT module; and
further comprising a plurality of IT modules each comprising the features of the first IT module, and a plurality of energy storage modules each comprising the features of the first energy storage module, each of the plurality of IT modules and plurality of energy storage modules in electrical communication with the first transformer module.

18. A modular data center system comprising:
a first information technology (“IT”) module comprising:
an enclosed structure comprising a first side wall and a second side wall, the first side wall and second side wall substantially parallel to a primary axis extending along the length of the first IT module; a first end wall; a second end wall; a floor; a ceiling;
subsystems disposed within the enclosed structure, the subsystems comprising IT equipment, energy storage system, and a power conversion system, wherein the IT equipment comprises at least one computer server or data storage device, wherein the energy storage systems comprise batteries capable of providing power to the IT equipment, wherein the power conversion system comprises at least one of a DC/DC converter, a DC/AC inverter, or an interface to medium-voltage transformer;
a control and monitoring system disposed within the first IT module, the control and monitoring system capable of: monitoring power demand of the IT equipment in the first IT module; controlling power flow between the IT equipment of the first IT module and the energy storage systems; and balancing the network data load in response to compute load variations experienced by the IT equipment; and
wherein the first IT module, the power conversion system, and the energy storage systems are disposed within the first IT module or otherwise integrated with the first IT module.

19. The modular data center system of claim 18 wherein the control and monitoring system of the first IT module is capable of providing uninterruptable power supply to the IT equipment.

20. A method for operating a modular data center, comprising:
monitoring power demand of a first information technology (“IT”) module, wherein the first information technology (“IT”) module comprises: an enclosed structure comprising a first side wall and a second side wall, the first side wall and second side wall substantially parallel to a primary axis extending along the length of the IT module; a first end wall; a second end wall; a floor; a ceiling; and subsystems disposed within the enclosed structure, the subsystems comprising IT equipment, wherein the IT equipment comprises at least one of a server or data storage device; and a control and monitoring system disposed within the IT module;
controlling power flow between the first IT module and a first energy storage module through a shared DC or AC connection, the first energy storage module comprising: an enclosed structure comprising a first side wall and a second side wall, the first side wall and second side wall substantially parallel to a primary axis extending along the length of the first energy storage module; a first end wall; a second end wall; a floor; a ceiling; an energy storage device disposed within the enclosed structure capable of providing a power supply to the IT equipment; a power conversion system capable of electrically coupling the first IT module with the first energy storage module; and
dynamically charging or discharging the first energy storage module in response to compute load variations experienced by the IT equipment.
